(19) United States
(12) Patent Application Publication
(10) Pub. No.: US 2026/0322144 A1
(43) Pub. Date: Oct. 15, 2026

(54) BATTERY CHARGING DEVICE, OPERATING METHOD OF THE SAME, AND MOBILE DEVICE INCLUDING THE SAME

(71) Applicant: SAMSUNG ELECTRONICS CO., LTD., Suwon-si (KR)

(72) Inventors: Jeongdu YOO, Suwon-si (KR); Hosung SON, Suwon-si (KR); Minkyu KWON, Suwon-si (KR); Sungwoo MOON, Suwon-si (KR); Kyungmin PARK, Suwon-si (KR); Sungwoo LEE, Suwon-si (KR); Daewoong CHO, Suwon-si (KR)

(73) Assignee: SAMSUNG ELECTRONICS CO., LTD., Suwon-si (KR)

(21) Appl. No.: 19/402,134

(22) Filed: Nov. 26, 2025

(30) Foreign Application Priority Data
Apr. 14, 2025 (KR) 10-2025-0048064

(51) Int. Cl. H02J 7/64; H02J 7/62; H02J 7/80

(52) U.S. Cl. CPC H02J 7/64; H02J 7/62; H02J 7/80

(57) ABSTRACT

A battery charging device includes a switching transistor having a triple well structure with a body terminal electrically connected to a first well region. A gate driving circuit provides a gate controller for adjusting a gate voltage applied to the gate of the switching transistor and a gate turn-off switch for selectively connecting the gate to a ground node. A body selector generates a first detection signal using a first voltage and a second voltage, and adjusts a voltage supplied to the body terminal. The body selector connects the body terminal to a node supplying the second voltage in response to the first detection signal and a delayed second detection signal, and connects the body terminal to the ground node in response to a third detection signal obtained by inverting the first detection signal.

### CROSS-REFERENCE TO RELATED APPLICATION(S)

This application claims benefit of priority to Korean Patent Application No. 10-2025-0048064 filed on Apr. 14, 2024, in the Korean Intellectual Property Office, the disclosure of which is incorporated herein by reference in its entirety.

### BACKGROUND

The present disclosure relates to a battery charging device, an operating method of the same, and a mobile device including the same.

As electronic devices become smaller and more powerful, the need for stable and efficient battery charging devices has increased. In general, a battery charging device may control a charging current or voltage according to a state of a battery. Recently, a charging control method using a switching transistor has been adopted to reduce power loss and improve the response speed of the circuit. The switching transistor is turned on and off according to a control signal, and may provide a power transmission path to the battery and the system. However, a technical means is required to effectively control problems such as voltage changes, leakage currents, or parasitic paths, which may occur depending on an operation of the switching transistor.

### SUMMARY

An aspect of the present disclosure is to provide a battery charging device preventing damage to a switching transistor and having improved performance, by preventing a gate-body voltage from exceeding a maximum voltage that the switching transistor may withstand due to an increase in a gate voltage

A battery charging device according to an example embodiment of the present disclosure includes: a switching transistor including a first well region doped with a first impurity, a second well region disposed within the first well region and doped with a second impurity, different from the first impurity, a source region and a drain region disposed within the second well region and doped with the first impurity, a body terminal disposed within the second well region and doped with the second impurity and electrically connected to the first well region, and a gate disposed between the source region and the drain region; a gate driving circuit including a gate controller receiving a first voltage and adjusting a gate voltage input to the gate, and a gate turn-off switch connected between a ground node supplying a ground voltage and the gate; and a body selector generating a first detection signal using the first voltage and a second voltage different from the first voltage, and adjusting a voltage supplied to the body terminal, and the body selector connects the body terminal to a node supplying the second voltage in response to the first detection signal and a second detection signal delaying the first detection signal during a predetermined time, and connecting the body terminal to the ground node in response to a third detection signal obtained by inverting the first detection signal.

An operating method of a battery charging device including a switching transistor having a triple well structure in which a first well region and a second well region disposed within the first well region and providing a body terminal are electrically connected to each other according to an example embodiment of the present disclosure includes: starting a supply of a first voltage to a gate of the switching transistor in a state in which the body terminal is connected to a ground node; comparing a second voltage different from the first voltage with the first voltage; when a value obtained by multiplying the first voltage by a first coefficient is greater than a value obtained by multiplying the second voltage by a second coefficient different from the first coefficient, separating the body terminal from the ground node, and supplying the second voltage to the body terminal through a resistance element; and short-circuiting a node supplying the second voltage with the body terminal when the body voltage reaches the second voltage and a predetermined time has elapsed.

A mobile device according to an example embodiment of the present disclosure includes: a system including a processor, a memory and a storage; a battery providing a power source for driving the system and charged by a system voltage generated by an external power source; and a battery charging device including a switching transistor controlling a supply of the system voltage to the battery and a body selector controlling a voltage supplied to a body terminal of the switching transistor, wherein the switching transistor has a triple well structure in which a first well region and a second well region disposed within the first well region and providing the body terminal are electrically connected to each other, at a first point in time, a supply of a first voltage to a gate of the switching transistor is started, and the battery charging device supplies a power source from the battery to the system, at a second point in time after the first point in time, the body selector separates the body terminal from a ground node and supplies a second voltage output from the battery to the body terminal through a resistance element, and at a third point in time after the second point in time, when the body voltage reaches the second voltage and a predetermined time has elapsed, the body selector short-circuits a node supplying the second voltage with the body terminal.

According to an example embodiment of the present disclosure, a battery charging device may include a switching transistor having a triple well structure in which a first well region and a second well region provided within the first well region are electrically connected to each other, thereby blocking a parasitic path formed in the switching transistor. A body selector included in the battery charging device senses a relative ratio of a first voltage and a second voltage to control a voltage supplied to the body terminal, thereby preventing a gate-body voltage from exceeding a maximum voltage that the switching transistor may withstand due to an increase in a gate voltage, and preventing damage to the switching transistor. By blocking a parasitic path formed in the switching transistor and preventing damage to the switching transistor, the performance of the battery charging device may be improved.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic view illustrating a mobile device according to an example embodiment of the present disclosure;

FIG. 2 is a block diagram illustrating a battery charging device according to an example embodiment of the present disclosure;

FIG. 3 is a schematic view illustrating a switching transistor according to an example embodiment of the present disclosure;

FIG. 4 is a schematic view illustrating a battery charging device according to an example embodiment of the present disclosure;

FIGS. 5 to 8 are schematic views illustrating a body selector according to an example embodiment of the present disclosure;

FIGS. 9 and 10 are views illustrating an operation of a battery charging device according to an example embodiment of the present disclosure;

FIGS. 11 to 15 are views illustrating an operation of a battery charging device according to an example embodiment of the present disclosure; and

FIG. 16 is a flowchart illustrating a method of operating a battery charging device according to an example embodiment of the present disclosure.

### DETAILED DESCRIPTION

Hereinafter, example embodiments of the present disclosure will be described with reference to the accompanying drawings.

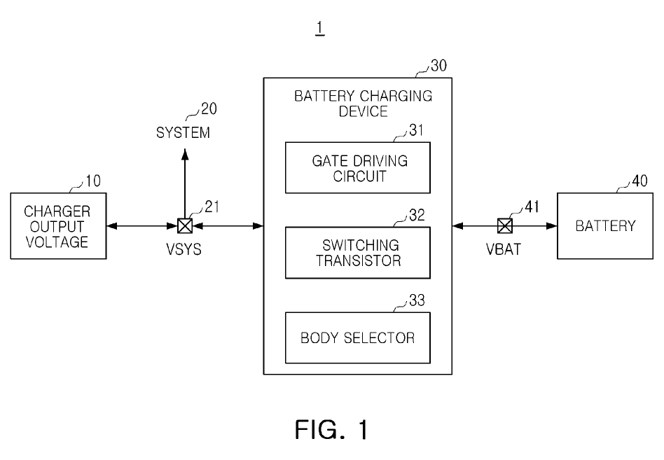

FIG. 1 is a simple view illustrating a mobile device according to an example embodiment of the present disclosure.

A mobile device 1 according to an example embodiment of the present disclosure may include a system 20, a battery charging device 30, and a battery 40.

A charger output voltage 10 may drive the system 20 and may charge the battery 40. Specifically, referring to FIG. 1, the charger output voltage 10 may supply power to the system 20 through a system voltage node 21, and may supply power to the battery 40 through the system voltage node 21 and a battery voltage node 41.

The charger output voltage 10 may be a voltage receiving power input from an external power source (e.g., a charger) and output after passing through a regulator, a protection circuit, and the like. The regulator may be a circuit adjusting an input voltage to a stable output voltage, and the protection circuit may be a circuit protecting a circuit and the battery 40 from conditions such as overvoltage, overcurrent, and abnormal temperature. For example, the regulator and the protection circuit may be included in the external power supply or may be included in the mobile device 1.

The charger output voltage 10 may vary depending on a type of charger. For example, a linear charger may linearly reduce an external input voltage and may provide a relatively constant and stable charger output voltage 10. A current charger may provide a flexible charger output voltage 10 depending on charging conditions and a control signal.

The system 20 may operate using the charger output voltage 10 and power supplied from the battery 40. The system 20 may include a processor, volatile or/and nonvolatile memory, and storage for storing data. The processor may perform various computational processing by executing instructions stored in the memory, and the storage may store an operating system, application programs, and data files to support an operation of the system 20. When power supply to the system 20 is interrupted, the operation of the system 20 may be limited or stopped.

The battery charging device 30 may include a gate driving circuit 31, a switching transistor 32, and a body selector 33. The switching transistor 32 may have a triple well structure in which a first well region and a second well region disposed within the first well region and providing a body terminal are electrically connected to each other. The gate driving circuit 31 may receive a gate control signal and may adjust a voltage supplied to a gate of the switching transistor 32 in response to the gate control signal. The body selector 33 may adjust a voltage supplied to a body terminal of the switching transistor 32.

In an example embodiment, the battery charging device 30 may include a system voltage node 21 providing a system voltage VSYS and a battery voltage node 41 providing a battery voltage VBAT. The system voltage node 21 may provide a path for supplying the charger output voltage 10 to the system 20, and may provide a path for supplying a power source from the battery voltage node 41 to the system 20. The system voltage node 21 may provide a path for supplying the charger output voltage 10 to the battery 40. The battery voltage node 41 may provide a path for supplying the charger output voltage 10 to the battery 40 and may provide a path for supplying a power source from the battery 40 to the system 20.

The battery 40 may store power and provide power for driving the system 20 even when the external power source is cut off. An output voltage of the battery 40 may be transmitted through the battery voltage node 41, and the battery voltage node 41 may be electrically connected to the battery 40, the battery charging device 30 and the system voltage node 21. Additionally, the battery 40 may be charged by the charger output voltage 10 output from the external power source.

In an example embodiment of the present disclosure, to smoothly provide a power transmission path of the battery charging device 30, the first well region and a body terminal of the switching transistor 32 may be electrically connected. Additionally, to prevent a gate-body voltage of the switching transistor 32 from increasing or excessive battery peak current from flowing and damaging the switching transistor 32, the body selector 33 may control a voltage supplied to the body terminal. Accordingly, the battery charging device 30 may operate stably, and the performance of the mobile device 1 may be improved.

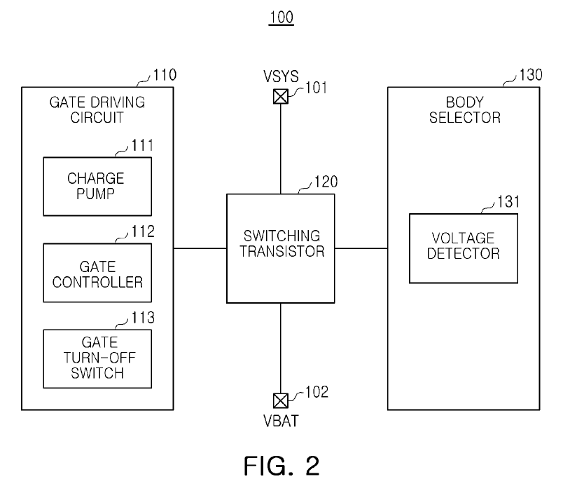

FIG. 2 is a block diagram simply illustrating a battery charging device according to an example embodiment of the present disclosure.

A battery charging device 100 according to an example embodiment of the present disclosure may include a gate driving circuit 110, a switching transistor 120, and a body selector 130. A drain region of the switching transistor may be connected to a system voltage node 101 supplying a system voltage VSYS, and a source region may be connected to a battery voltage node 102 supplying a battery voltage VBAT.

The gate driving circuit 110 may include a charge pump 111, a gate controller 112, and a gate turn-off switch 113. The charge pump 111 may input a voltage to the gate controller 112, and the gate controller 112 may supply a voltage to a gate of the switching transistor 120.

The charge pump 111 may be a voltage conversion circuit generating a voltage higher or lower than an input voltage using an internal capacitor. The charge pump 111 may receive the battery voltage VBAT and may stably provide a voltage higher than the battery voltage VBAT to the battery charging device 100 based on the battery voltage VBAT.

The charge pump 111 according to an example embodiment of the present disclosure may output a first voltage higher than the battery voltage VBAT and may input the first voltage to the gate controller 112. The first voltage may be a sum of the battery voltage VBAT and a selected power voltage. In an example embodiment, the selected power voltage may be a maximum power voltage selected from the power voltages within a chip implementing the mobile device.

The gate controller 112 may receive a gate control signal and may supply a voltage for driving the switching transistor 120. The gate controller 112 may control a voltage provided to the switching transistor 120, and may supply a voltage between the battery voltage VBAT and the first voltage. The gate controller 112 may receive the first voltage and may adjust a gate voltage applied to the switching transistor 120 according to the gate control signal based thereon. The gate controller 112 may selectively output an appropriate voltage according to the gate control signal, and may turn on the switching transistor 120 or may adjust the power transmission path.

One end of the gate turn-off switch 113 may be electrically connected to a gate of the gate controller 112 and the switching transistor 120, and the other end of the gate turn-off switch 113 may be connected to a ground node. When the gate turn-off switch 113 is turned on, the gate of the switching transistor 120 may be connected to the ground node. When the gate of the switching transistor 120 is connected to the ground node, the body terminal of the switching transistor 120 may be connected to the ground node, and no current may flow to the battery voltage node 102. In other words, a case in which the gate turn-off switch 113 is turned on may be a state in which the battery charging device 100 completely blocks the power transmission path, and may be a state in which the mobile device does not use any power stored in the battery at all.

When the gate turn-off switch 113 is turned off, the gate of the switching transistor 120 may be separated from the ground node and may receive a voltage output from the gate controller 112. When the gate turn-off switch 113 is turned off and the voltage is supplied to the gate of the switching transistor 120, the body terminal of the switching transistor 120 may be separated from the ground node and may be connected to the battery voltage node 102. In other words, a case in which the gate turn-off switch 113 is turned off may be any state other than a state in which the battery charging device 100 completely blocks the power transmission path, and may be a state in which the mobile device uses the power stored in a battery. However, the present disclosure is not limited thereto, and when the gate turn-off switch 113 is turned off, the mobile device may use a charger output voltage without using the power stored in the battery.

The switching transistor 120 may be turned on or turned off to control the flow of current. Depending on the voltage supplied to the gate or the body terminal of the switching transistor 120, a power path may be opened or closed or the voltage may be switched. According to an example embodiment of the present disclosure, the switching transistor 120 may be turned on to provide a power supply path or may be turned off to block the power supply path depending on the voltage applied to the gate.

For example, in the case of charging the battery, the switching transistor 120 may form a power supply path from the system voltage node 101 to the battery voltage node 102. In the case of using power stored in the battery, the switching transistor 120 may form a power supply path from the battery voltage node 102 to the system voltage node 101.

The switching transistor 120 may have a triple well structure in which the first well region and the second well region disposed within the first well region and providing the body terminal are electrically connected to each other. The first well region may be doped with a first impurity, and the second well region may be doped with a second impurity, different from the first impurity. When regions doped with different impurities are adjacent to each other, a parasitic path impeding the flow of current may be formed. To prevent the formation of the parasitic path in the switching transistor 120, the first well region and the second well region doped with different impurities may be electrically connected. For example, the switching transistor 120 may be an N-type transistor, and the first impurity may be an N-type impurity, and the second impurity may be a P-type impurity. As the first well region and the second well region are electrically connected to each other, the battery charging device 100 may provide a stable power transmission path.

The body selector 130 may adjust the voltage input to the body terminal of the switching transistor 120. The body selector 130 may connect the body terminal to the ground node to provide the ground voltage, and may connect the body terminal to the battery voltage node 102 to provide the battery voltage VBAT.

In an example embodiment, the body selector 130 may include a voltage detector 131 outputting a detection signal. The voltage detector 131 may sense a relative ratio of a first voltage generated by the charge pump 111 and a battery voltage VBAT and may generate a first detection signal. Additionally, the voltage detector 131 may generate a second detection signal delaying the first detection signal during a predetermined time, and a third detection signal obtained by inverting the first detection signal.

The body selector 130 may connect the body terminal of the switching transistor 120 to the battery voltage node 102 in response to the first detection signal and the second detection signal generated by the voltage detector 131. The body selector 130 may separate the body terminal from the ground node in response to the third detection signal. For example, the first detection signal and the second detection signal may be logic high, and the third detection signal may be logic low.

In an example embodiment of the present disclosure, by electrically connecting the first well region and the second well region of the switching transistor 120, the battery charging device 100 may provide a stable power transmission path. Additionally, by sensing a relative ratio of the first voltage and the battery voltage VBAT in the voltage detector 131 and generating the first detection signal, the voltage of the gate-body of the switching transistor 120 may be stably maintained, and excessive battery peak current may be prevented from flowing to the battery charging device 100. Accordingly, the switching transistor 120 may be prevented from being damaged, and the battery charging device 100 having improved performance and operating stably may be provided.

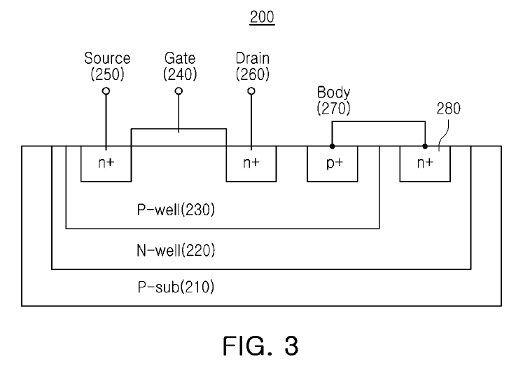

FIG. 3 is a view simply illustrating a switching transistor according to an example embodiment of the present disclosure.

A switching transistor 200 according to an example embodiment of the present disclosure may have a triple well structure. Referring to FIG. 3, a switching transistor 200 may include a first well region 220 doped with a first impurity, and a second well region 230 disposed within the first well region 220 and doped with a second impurity, different from the first impurity. The first well region 220 may be disposed on a substrate 210 doped with the second impurity. The first well region 220 may include a first deep well region 280 doped with the first impurity. For example, the switching transistor 200 may be an N-type transistor, and the first impurity may be an N-type impurity, and the second impurity may be a P-type impurity.

The switching transistor 200 may include a source region 250 and a drain region 260 disposed in the second well region 230 and doped with the first impurity, and may include a gate 240 disposed between the source region 250 and the drain region 260. A body terminal 270 doped with the second impurity may be disposed in the second well region 230. The body terminal 270 may be electrically connected to the first well region 220 and/or the first deep well region 280.

The source region 250 of the switching transistor 200 may be connected to a battery voltage node supplying a battery voltage, and the drain region 260 may be connected to a system voltage node providing a system voltage. The gate 240 may be connected to the gate driving circuit to receive a first voltage, and the body terminal 270 may be connected to a body selector to receive a battery voltage or a ground voltage.

In a comparative example, the highest power voltage within a chip driving the mobile device may be input to the first well region 220 and/or the first deep well region 280 of the switching transistor 200 having a triple well structure, and the lowest voltage within the chip may be input to the body terminal 270. A magnitude of the battery voltage supplied to the source region 250 and a magnitude of the system voltage supplied to the drain region 260 may be fluid. When at least one voltage in a magnitude of the battery voltage supplied to the source region 250, a magnitude of the system voltage supplied to the drain region 260, a magnitude of the voltage supplied to the first well region 220, and a magnitude of the voltage supplied to the body terminal 270 increases or decreases, a parasitic diode path and a parasitic BJT impeding the flow of current may be formed in the switching transistor 200.

In an example embodiment, the parasitic diode path may be formed in the switching transistor 200. When a region doped with the first impurity and a region doped with the second impurity are adjacent to each other, the parasitic diode path may be formed between the regions doped with different impurities. For example, the parasitic diode path may be formed between the second well region 230 and the source region 250.

When a direction of the formed parasitic diode path and a direction of the power supply path of the battery charger are different from each other, the parasitic diode path may impede the flow of current and may deteriorate the performance of the battery charger. For example, the parasitic diode path may be formed between the source region 250 and the second well region 230, between the drain region 260 and the second well region 230, between the second well region 230 and the first well region 220, and between the first well region 220 and the substrate 210, and the direction of the parasitic diode path may be formed in direction oriented from the region doped with the second impurity to the region doped with the first impurity.

In the switching transistor 200 according to an example embodiment of the present disclosure, the body terminal 270 and the first well region 220 may be electrically connected, the formation of an undesired parasitic diode path may be prevented. In a state in which the battery charging device completely blocks the power transmission path, the body terminal 270 may be connected to the ground node. As the body terminal 270 is connected to the ground node, the formation of the parasitic diode path in the switching transistor 200 may be prevented.

When the battery charging device does not completely block the power transmission path, the body terminal 270 may be connected to a battery voltage node supplying the battery voltage. When the battery voltage is supplied to the body terminal 270, only a parasitic diode path in which a path is formed from the battery voltage to the system voltage may be formed. In other words, the parasitic diode path in which a path is formed from the body terminal 270 to which the battery voltage is supplied to the drain region 260 to which the system voltage is supplied may be formed.

In an example embodiment, a parasitic BJT component may be formed in the switching transistor 200. The parasitic BJT may include an NPN BJT and a PNP BJT. For example, the parasitic NPN BJT component may be formed between the source region 250 and/or the drain region 260 doped with the first impurity, the second well region 230 doped with the second impurity, and the first well region 220 doped with the first impurity. The parasitic PNP BJT component may be formed between the second well region 230 doped with the second impurity, the first well region 220 doped with the first impurity, and the substrate 210 doped with the second impurity. When the parasitic NPN BJT component is turned on and current begins to flow, the parasitic PNP BJT formed adjacent to the parasitic NPN BJT component may also be turned on and current may begin to flow. A relatively high current may flow to the switching transistor 200 due to a positive feedback action formed between the parasitic NPN BJT and the parasitic PNP BJT, and a latch-up phenomenon may occur in the switching transistor 200 or the switching transistor 200 may be destroyed.

In the switching transistor 200 according to an example embodiment of the present disclosure, the body terminal 270 may be electrically connected to the first well region 220, thereby preventing the formation of the parasitic BJT component. In other words, the first well region 220 and the body terminal 270 doped with different impurities may be electrically connected to each other, thereby preventing a latch-up phenomenon from being caused by forming the parasitic NPN BJT and the parasitic PNP BJT in the switching transistor 200, or preventing damage to the switching transistor 200.

In an example embodiment of the present disclosure, as the body terminal 270 of the switching transistor 200 is electrically connected to the first well region 220 and/or the first deep well region 280, it may be possible to prevent the formation of a parasitic path impeding the flow of current in the switching transistor 200. Accordingly, the switching transistor 200 may be prevented from being damaged, and a stable power transmission path may be provided, thereby improving the performance of the battery charging device.

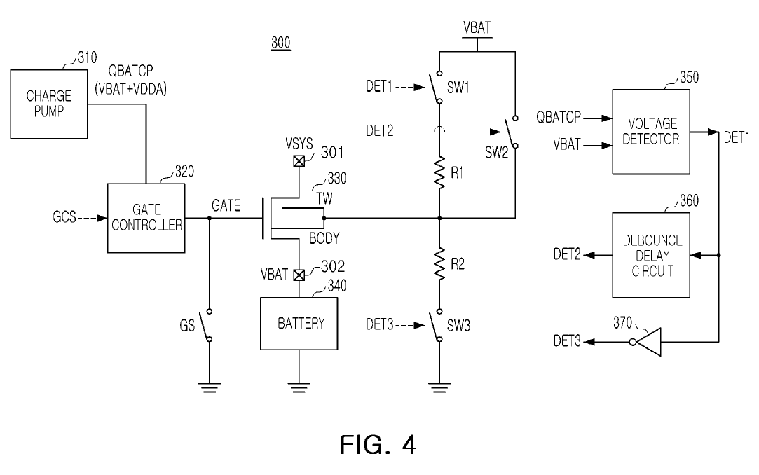

FIG. 4 is a simple view illustrating a battery charging device according to an example embodiment of the present disclosure.

A battery charging device 300 according to an example embodiment of the present disclosure may include a charge pump 310, a gate controller 320, a switching transistor 330, and a voltage detector 350.

The charge pump 310 may output a first voltage QBATCP and may supply the first voltage QBATCP to the gate controller 320. The first voltage QBATCP may be the sum of a second voltage VBAT and a selected power voltage VDDA. The second voltage VBAT may be a voltage output from a battery 340, and the selected power voltage VDDA may be a maximum power voltage selected within a chip implementing a mobile device.

The gate controller 320 may receive a gate control signal GCS and may provide a voltage for driving the switching transistor 330. The gate controller 320 may receive the first voltage QBATCP output from the charge pump 310 and may selectively output an appropriate voltage according to the gate control signal GCS. The battery charging device 300 may be switched to a state in which the power transmission path is completely blocked, a state in which a full power transmission is permitted, a current control state, a voltage control state, or the like, according to the gate control signal GCS.

When a gate turn-off switch GS is turned on, the battery charging device 300 may operate in a state in which the power transmission path is completely blocked. A gate GATE of the switching transistor 330 may be connected to a ground node supplying a ground voltage, and a body terminal BODY of the switching transistor 330 may also be connected to the ground node.

When the gate turn-off switch GS is turned off, the battery charging device 300 may operate in any state other than a state in which the power transmission path is completely blocked. When the gate turn-off switch GS is turned off, the body terminal BODY of the switching transistor 330 may be connected to a battery voltage node 302 supplying the second voltage VBAT.

The switching transistor 330 may have a triple well structure in which a first well region TW and a second well region disposed within the first well region TW and providing the body terminal BODY are electrically connected to each other. A source region of the switching transistor 330 may be connected to the battery 340 through the battery voltage node 302. A drain region of the switching transistor 330 may be connected to an external power source and a system through a system voltage node 301. The body terminal BODY of the switching transistor 330 may be connected to a body selector.

The body selector may generate a first detection signal DET1 using the first voltage QBATCP and the second voltage VBAT, and may adjust a voltage supplied to the body terminal BODY. The body selector may sense a relative ratio of the first voltage QBATCP and the second voltage VBAT, and may generate a first detection signal DET1 of logic high when the first voltage QBATCP increases to a level higher than the second voltage VBAT. In an example embodiment, sensing the relative ratio of the first voltage QBATCP and the second voltage VBAT may mean comparing a value obtained by multiplying the first voltage QBATCP by a first coefficient and a value obtained by multiplying the second voltage VBAT by a second coefficient different from the first coefficient. For example, the first coefficient and the second coefficient may be greater than 0 and less than or equal to 1, respectively.

The body selector may generate a first detection signal DET1, a second detection signal DET2 delaying the first detection signal DET1 during a predetermined time, and a third detection signal DET3 obtained by inverting the first detection signal DET1. In an example embodiment, the predetermined time may be determined according to the capacity of the battery 340 and a magnitude of a first resistor R1. The body selector may supply the second voltage VBAT to the body terminal BODY in response to the first detection signal DET1 and the second detection signal DET2, and may supply a ground voltage to the body terminal BODY in response to the third detection signal DET3.

Referring to FIG. 4, the body selector may include a first switch SW1 connected between the body terminal BODY and the battery voltage node 302 and turned on in response to a first detection signal DET1, a second switch SW2 connected in parallel with the first switch SW1 between the body terminal BODY and the battery voltage node 302 and turned on in response to the second detection signal DET2, and a third switch SW3 connected between the body terminal BODY and the ground node and turned on in response to the third detection signal DET3.

Additionally, the body selector may include a first resistor R1 connected between the body terminal BODY and the first switch SW1, and a second resistor R2 connected between the body terminal BODY and the third switch SW3. In an example embodiment, the first resistor R1 may be connected between the first switch SW1 and the battery voltage node 302, and the second resistor R2 may be connected between the third switch SW3 and the ground node. For example, a magnitude of the first resistor R1 may be greater than a magnitude of the second resistor R2.

The body selector may include a voltage detector 350 generating first to third detection signals DET1 to DET3. The voltage detector 350 may receive a first voltage QBATCP and a second voltage VBAT, and may compare the first voltage QBATCP and the second voltage VBAT to output the first detection signal DET1. By comparing relative ratios of the first voltage QBATCP and the second voltage VBAT to control the voltage supplied to the body terminal BODY, the body selector may change the voltage supplied to the body terminal BODY while maintaining the gate-body voltage, which is a difference between the gate voltage GATE and a voltage of the body terminal BODY, in a stable range in which the switching transistor 330 is not damaged.

A debounce delay circuit 360 and an inverter 370 may be connected to the output terminal of the voltage detector 350. The debounce delay circuit 360 may receive the first detection signal DET1 and may output the second detection signal DET2 delayed during a predetermined time. For example, the predetermined time may be determined according to the capacity of the battery 340 and the magnitude of the first resistor R1. The inverter 370 may receive the first detection signal DET1 and may output the third detection signal DET3 obtained by inverting the first detection signal DET1.

In a state in which the battery charging device 300 completely blocks the power transmission path, the gate GATE of the switching transistor 330 may be connected to a ground node and the body terminal BODY may also be connected to the ground node. When the battery charger 300 completely blocks the power transmission path, the battery 340 may be in a discharged state or may be in a state of not being charged by an external power source.

To switch the battery charger 300 from a state in which the power transmission path is completely blocked to a state in which the full power transmission is permitted, the gate turn-off switch GS connected to both the gate GATE of the switching transistor 330 and the ground node may be turned off. The gate controller 320 may receive the gate control signal GCS, and may supply the first voltage QBATCP to the gate GATE of the switching transistor 330.

The charge pump 310 may output the first voltage QBATCP, and may input the first voltage QBATCP to the gate controller 320. When the first voltage QBATCP is on a level lower than that of the second voltage VBAT, the voltage detector 350 may generate the first detection signal DET1 of logic low. In response to the first detection signal DET1, the first switch SW1 may be turned off, and in response to the third detection signal DET3, the third switch SW3 may be turned on. Accordingly, the body terminal BODY may be connected to the ground node, and a ground voltage may be provided to the body terminal BODY.

The gate voltage may increase in the same trend as the first voltage QBATCP output from the charge pump 310. When the first voltage QBATCP increases to a level higher than that of the second voltage VBAT, the voltage detector 350 may generate the first detection signal DET1 of logic high. In response to the first detection signal DET1, the first switch SW1 may be turned on, and in response to the third detection signal DET3, the third switch SW3 may be turned off. As the first switch SW1 is turned on, the second voltage VBAT may be supplied to the body terminal BODY through the first resistor R1.

When the voltage of the body terminal BODY changes abruptly from the ground voltage to the second voltage VBAT, a threshold voltage of the switching transistor 330 may change due to the body effect. When the threshold voltage of the switching transistor 330 changes, an excessive battery peak current may occur in a direction toward the system voltage node 301 in the battery voltage node 302, which may cause damage to the switching transistor 330 or deteriorate the performance of the battery charging device 300. Accordingly, the second voltage VBAT may be slowly supplied to the body terminal BODY through the first resistor R1, thereby preventing the voltage of the body terminal BODY from rapidly changing from the ground voltage to the second voltage VBAT.

The debounce delay circuit 360 may output the second detection signal DET2 delaying the first detection signal DET1 during a predetermined time. In response to the second detection signal DET2, the second switch SW2 may be turned on, and the body terminal BODY may be directly connected to the battery voltage node 302. Since the body terminal BODY and the battery voltage node 302 are directly connected, the second voltage VBAT may be stably supplied to the body terminal BODY.

When the gate turn-off switch GS is turned on, the battery charger 300 may be switched from a state of permitting the full power transmission to a state of completely blocking the power transmission path. The supply of the first voltage QBATCP to the gate GATE may be interrupted and the ground voltage may be supplied, and the supply of the second voltage VBAT may also be interrupted and the ground voltage may be supplied to the body terminal BODY.

When a first speed at which the gate GATE voltage decreases from the first voltage QBATCP to the ground voltage and a second speed at which the body terminal BODY voltage decreases from the second voltage VBAT to the ground voltage are different from each other, the switching transistor 330 may be damaged as the gate-body voltage increases. To prevent the switching transistor 330 from being damaged, the second resistor R2 may be disposed between the body terminal BODY and the ground node. By controlling the magnitude of the second resistor R2, the second speed at which the voltage of the body terminal BODY decreases from the second voltage VBAT to the ground voltage may be adjusted.

According to an example embodiment of the present disclosure, the battery charging device 300 may include the switching transistor 330 having the triple well structure in which the first well region and a second well region disposed within the first well region and providing the body terminal BODY are electrically connected to each other, so that a parasitic path formed in the switching transistor 330 may be blocked, and a power transmission path of the battery charging device 300 may be smoothly provided. The body selector included in the battery charging device 300 may sense the relative ratios of the first voltage QBATCP and the second voltage VBAT and may control the voltage supplied to the body terminal BODY, so that the gate-body voltage may be maintained in a stable range in which the switching transistor 330 is not damaged. The performance of the battery charging device 300 may be improved by smoothly providing the power transmission path of the battery charging device 300 and stably maintaining the gate-body voltage.

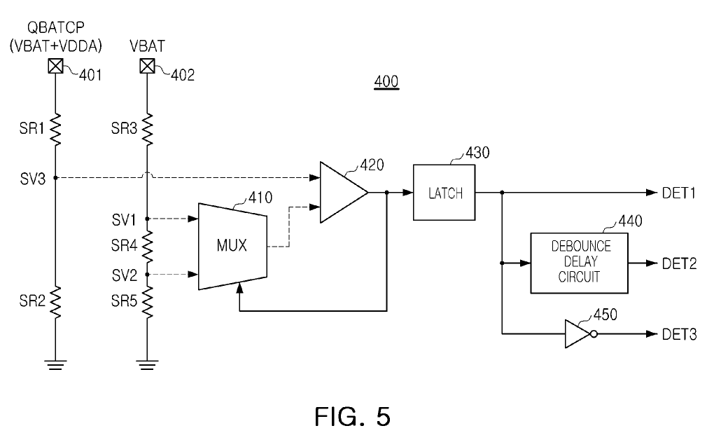

FIGS. 5 to 8 are views simply illustrating a body selector according to an example embodiment of the present disclosure.

First, in an example embodiment illustrated in FIG. 5, a body selector 400 may include a multiplexer 410, a comparator 420, a latch 430, a debounce delay circuit 440, and an inverter 450.

The body selector 400 may sense the relative ratios of a first voltage QBATCP and a second voltage VBAT. A first sensing resistor SR1 and a second sensing resistor SR2 may be connected in series, between a first voltage node 401 supplying the first voltage QBATCP and a ground node supplying a ground voltage. For example, the first sensing resistor SR1 may be greater than the second sensing resistor SR2. However, the present disclosure is not limited thereto.

A third sensing resistor SR3, a fourth sensing resistor SR4, and a fifth sensing resistor SR5 may be connected in series between a second voltage node 402 supplying the second voltage VBAT and the ground node. For example, the third sensing resistor SR3 may be greater than the fourth sensing resistor SR4, and the fourth sensing resistor SR4 may be greater than the fifth sensing resistor SR5. However, the present disclosure is not limited thereto.

The multiplexer 410 may select and output one of a first sensing voltage SV1 applied to the fourth sensing resistor SR4 and the fifth sensing resistor SR5, and a second sensing voltage SV2 applied to the fifth sensing resistor SR5. For example, a value obtained by multiplying the second voltage VBAT by a second coefficient may be the first sensing voltage SV1 or the second sensing voltage SV2. When the value obtained by multiplying the second voltage VBAT by the second coefficient is the first sensing voltage SV1, the second coefficient may be a value obtained by dividing a sum of the fourth sensing resistor SR4 and the fifth sensing resistor SR5 by a sum of the third sensing resistor SRb, the fourth sensing resistor SR4 and the fifth sensing resistor SR5. When the value obtained by multiplying the second voltage VBAT by the second coefficient is the second sensing voltage SV2, the second coefficient may be a value obtained by dividing the fifth sensing resistor SR5 by the sum of the third sensing resistor SR3, the fourth sensing resistor SR4 and the fifth sensing resistor SR5.

A voltage output from the multiplexer 410 may be input to the comparator 420. The voltage output from the multiplexer 410 may be input to the comparator 420 to improve the stability of the signal output from the comparator 420. However, the present disclosure is not limited to the configuration illustrated in FIG. 5, and the multiplexer 410 may not be included in the body selector 400.

The comparator 420 may receive a third sensing voltage SV3 applied to the second sensing resistor SR2 and the voltage output from the multiplexer 410, and may compare the third sensing voltage SV3 and the output voltage to output the first detection signal DET1. For example, a value obtained by multiplying the first voltage QBATCP by the first coefficient may be the third sensing voltage SV3. When the value obtained by multiplying the first voltage QBATCP by the first coefficient is the third sensing voltage SV3, the first coefficient may be a value obtained by dividing the second sensing resistor SR2 by the sum of the first sensing resistor SR1 and the second sensing resistor SR2. When the third sensing voltage SV3 increases by a level higher than that of the voltage output from the multiplexer 410, the comparator 420 may output the first detection signal DET1 of logic high. The first detection signal DET1 output from the comparator 420 may be input as a selection signal of the multiplexer 410. For example, when the first detection signal DET1 is logic high, the multiplexer 410 may output the second sensing voltage SV2. However, the present disclosure is not limited to the configuration illustrated in FIG. 5, and the first sensing voltage SV1 or the second sensing voltage SV2 may be directly input to the comparator 420.

The latch 430 may store the first detection signal DET1 output from the comparator 420. By the latch 430 storing the first detection signal DET1, even if the first voltage QBATCP temporarily decreases, a voltage supplied to the body terminal of the switching transistor may be maintained.

In response to the first detection signal DET1 output from the latch 430, the first switch is turned on, and a second voltage VBAT may be supplied to the body terminal through the resistor element. The debounce delay circuit 440 connected to the output terminal of the latch 430 may output a second detection signal DET2 delaying the first detection signal DET1 for a predetermined time.

In response to the second detection signal DET2, the second switch may be turned on, and may be directly connected to the second voltage node 402 in the body terminal. The inverter 450 connected to the output terminal of the latch 430 may output a third detection signal DET3 obtained by inverting the first detection signal DET1. When the first detection signal DET1 is logic high, the third detection signal DET3 may be logic low, and the third switch may be turned off in response to the third detection signal DET3, and the body terminal may be separated from the ground node.

The body selector 400 according to an example embodiment of the present disclosure may sense the relative ratios of the first voltage QBATCP and the second voltage VBAT and may adjust the voltage supplied to the body terminal, so that the gate-body voltage may be maintained in a range in which the switching transistor is not damaged. The multiplexer 410 may improve the stability of the first detection signal DET1 output from the comparator 420. The latch 430 may stably maintain the voltage supplied to the body terminal by outputting the first detection signal DET1 stored in the latch 430, even if the first voltage QBATCP is temporarily unstable. Accordingly, a smooth power transmission path of the battery charger may be provided and the gate-body voltage may be maintained within a stable range, thereby improving the performance of the battery charger.

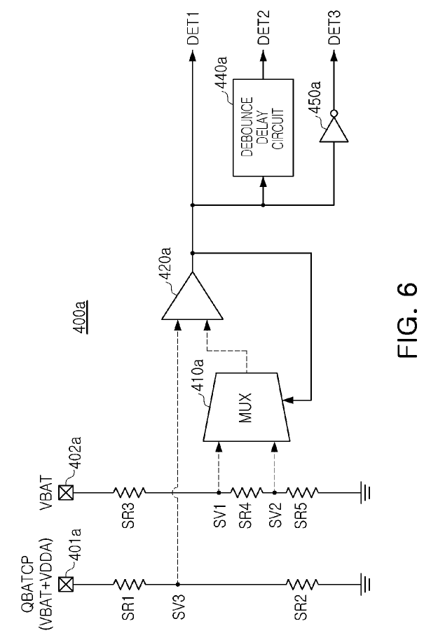

A body selector 400a according to an example embodiment illustrated in FIG. 6 may share technical features identical to or equivalent to those of the body selector 400 described in FIG. 5 above. Accordingly, the description overlapping the configuration described in FIG. 5 will be simplified or omitted.

In an example embodiment illustrated in FIG. 6, the body selector 400a may include a multiplexer 410a, a comparator 420a, a debounce delay circuit 440a, and an inverter 450a.

The multiplexer 410a may receive a first sensing voltage SV1 and a second sensing voltage SV2, and may output one of the first sensing voltage SV1 and the second sensing voltage SV2. A voltage output from the multiplexer 410a may be input to the comparator 420a.

The voltage output from the multiplexer 410a and the third sensing voltage SV3 may be input to the comparator 420a, and the first detection signal DET1 may be output. When the third sensing voltage SV3 is greater than the voltage output from the multiplexer 410a, the comparator 420a may output the first detection signal DET1 of logic high. The first detection signal DETb may be input as a selection signal of the multiplexer 410a.

When the first switch is turned on in response to the first detection signal DET1, the body selector 400a may connect the body terminal to a second voltage node 402a through the resistance element. When the second switch is turned on in response to the second detection signal DET2 output from the debounce delay circuit 440a, the body selector 400a may directly connect the body terminal to the second voltage node 402a. When the third switch is turned off in response to the third detection signal DET3 output from the inverter 450a, the body selector 400a may separate the body terminal from the ground node.

The body selector 400a according to an example embodiment of the present disclosure may sense the relative ratios of the first voltage QBATCP and the second voltage VBAT and may adjust the voltage supplied to the body terminal, so that the gate-body voltage may be maintained in a range in which the switching transistor is not damaged. The multiplexer 410a may improve the stability of the first detection signal DET1 output from the comparator 420a. Accordingly, the gate-body voltage may be stably maintained to improve the performance of the battery charging device.

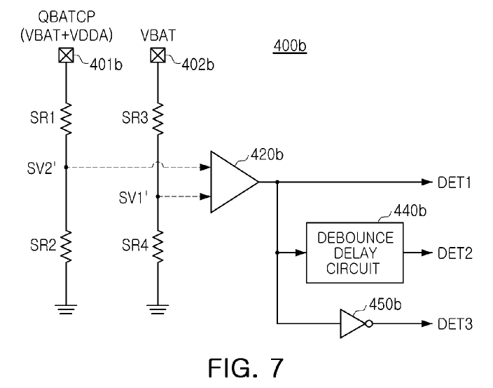

A body selector 400b according to an example embodiment illustrated in FIG. 7 may share the technical features identical to or equivalent to the body selector 400 described in FIG. 5 above. Accordingly, the description overlapping the configuration described in FIG. 5 will be simplified or omitted.

In an example embodiment illustrated in FIG. 7, the body selector 400b may include a comparator 420b, a debounce delay circuit 440b, and an inverter 450b. The multiplexer 410 and the latch 430 illustrated in FIG. 5 may not be included in an example embodiment illustrated in FIG. 7.

Referring to FIG. 7, the first sensing resistor SR1 and the second sensing resistor SR2 may be connected in series between a first voltage node 401b supplying a first voltage QBATCP and a ground node supplying a ground voltage. The third sensing resistor SR3 and the fourth sensing resistor SR4 may be connected in series between a second voltage node 402b supplying a second voltage VBAT and the ground node.

The comparator 420b may compare a first sensing voltage SV1` applied to the fourth sensing resistor SR4 and a second sensing voltage SV2` applied to the second sensing resistor SR2 to output a first detection signal DET1. The first sensing voltage SV1` may be a value obtained by multiplying the second voltage VBAT by the second coefficient, and the second sensing voltage SV2` may be a value obtained by multiplying the first voltage QBATCP by the first coefficient. The second coefficient may be a value obtained by dividing the fourth sensing resistor SR4 by the sum of the third sensing resistor SR3 and the fourth sensing resistor SR4, and the first coefficient may be a value obtained by dividing the second sensing resistor SR2 by the sum of the first sensing resistor SR1 and the second sensing resistor SR2. For example, when the second sensing voltage SV2` is greater than the first sensing voltage SV1`, the comparator 420b may output a first detection signal DET1 of logic high.

The body selector 400b according to an example embodiment of the present disclosure senses the relative ratios of the first voltage QBATCP and the second voltage VBAT and may adjust the voltage supplied to the body terminal, thereby maintaining the gate-body voltage within a range in which the switching transistor is not damaged. Accordingly, the gate-body voltage may be stably maintained to improve the performance of the battery charging device.

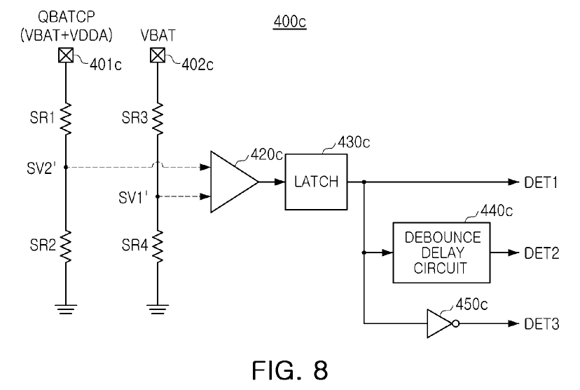

A body selector 400c according to an example embodiment illustrated in FIG. 8 may share the technical features identical to or equivalent to the body selector 400b examined in FIG. 7. Accordingly, descriptions overlapping the configuration described in FIG. 7 will be simplified or omitted.

In an example embodiment illustrated in FIG. 8, the body selector 400c may include a comparator 420c, a latch 430c, a debounce delay circuit 440c, and an inverter 450c. The body selector 400c illustrated in FIG. 8 may be obtained by adding the latch 430c to the body selector 400b illustrated in FIG. 7.

The comparator 420c may compare the first sensing voltage SV1` and the second sensing voltage SV2` and may output the first detection signal DET1. The first detection signal DET1 output from the comparator 420c may be stored in the latch 430c. In an example embodiment of the present disclosure, by storing the first detection signal DET1 in the latch 430c, even if the first voltage QBATCP is temporarily unstable, the body selector 400c may stably maintain the voltage supplied to the body terminal.

The body selector 400c according to an example embodiment of the present disclosure may sense the relative ratios of the first voltage QBATCP and the second voltage VBAT and may adjust the voltage supplied to the body terminal, so that the gate-body voltage may be maintained within a range in which the switching transistor is not damaged. The latch 430c may stably maintain the body voltage by outputting the first detection signal DET1 even if the first voltage QBATCP is temporarily unstable. Accordingly, the gate-body voltage may be stably maintained to improve the performance of the battery charging device.

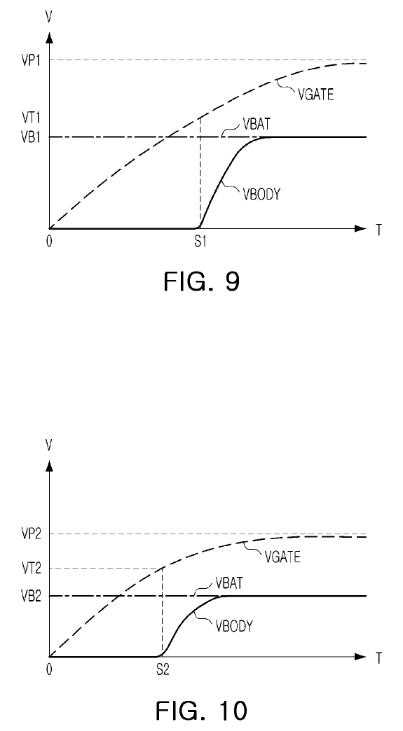

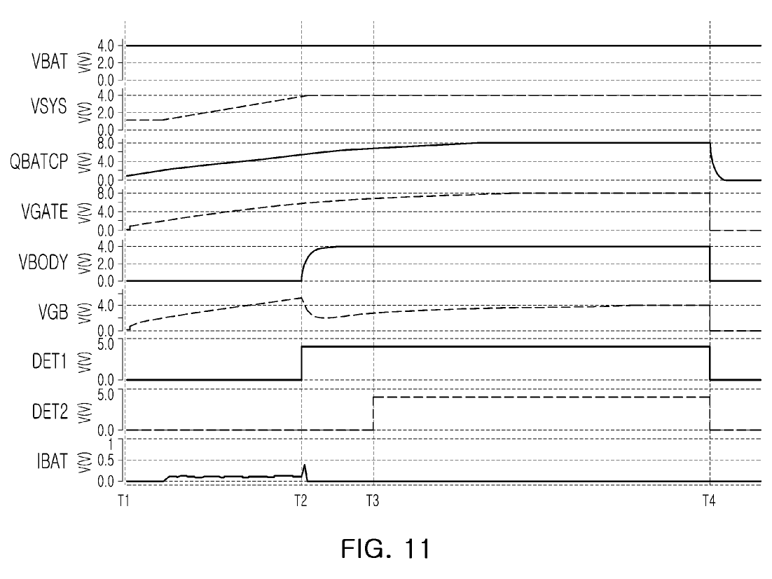

FIGS. 9 and 10 are views illustrating an operation of a battery charging device according to an example embodiment of the present disclosure.

The body selector according to an example embodiment of the present disclosure may sense relative ratios of a first voltage and a second voltage VBAT different from the first voltage, so that a difference between a gate voltage VGATE and a body voltage VBODY of a switching transistor may be stably maintained, and the body voltage VBODY may be switched even if the second voltage VBAT decreases.

First, referring to FIG. 9, the battery charging device may be switched from a state in which the power transmission path is completely blocked to a state in which the full power transmission is permitted. The gate controller may receive the first voltage output from the charge pump, and may supply the first voltage to the gate of the switching transistor. The first voltage output from the charge pump and the gate voltage VGATE may increase in the same trend. Regardless of the state of the battery charging device, the second voltage VBAT may be maintained at VB1.

The first voltage may increase by a first target voltage VP1, and the gate voltage VGATE may also increase by the first target voltage VP1 in the same trend as the first voltage. The first voltage may be a value obtained by adding a selected power voltage to the second voltage VBAT. In an example embodiment, the selected power voltage may be a maximum power voltage selected from power voltages within the chip implementing the mobile device.

While the gate voltage VGATE increases, the gate voltage VGATE may reach a first trigger voltage VT1. The first trigger voltage VT1 may be a voltage of a lower level than that of the first target voltage VP1, and the first trigger voltage VT1 may be determined according to the second voltage VBAT. At a first point in time S1 at which the gate voltage VGATE reaches the first trigger voltage VT1, the body selector may generate a first detection signal of logic high.

At the first point in time S1, the body selector may generate a first detection signal and a third detection signal obtained by inverting the first detection signal. In response to the third detection signal, the body terminal may be separated from the ground node, and the body terminal may be connected to the second voltage node supplying the second voltage VBAT through a resistor element in response to the first detection signal. Since the body terminal receives the second voltage VBAT through the resistor element, the body voltage VBODY may slowly increase from the ground voltage to the second voltage VBAT.

In an example embodiment of the present disclosure, as the body selector senses the relative ratio of the first voltage and the second voltage VBAT, the first trigger voltage VT1 that starts outputting the first detection signal of high logic may also be fluid. As a level of the second voltage VBAT decreases, the first trigger voltage VT1 may also decrease. Since the first trigger voltage VT1 is determined according to the second voltage VBAT, it may be possible to ensure that the body voltage VBODY increases by the second voltage VBAT even if the second voltage VBAT decreases. By ensuring that the body voltage VBODY increases from the ground voltage to the second voltage VBAT, it may be possible to prevent a switching transistor from being damaged due to a difference between the gate voltage VGATE and the body voltage VBODY.

Referring to FIGS. 9 and 10 together, the second voltage VBAT illustrated in FIG. 10 may be lower than the second voltage VBAT illustrated in FIG. 9. For example, an example embodiment illustrated in FIG. 10 is a case in which the battery is discharged, and the discharged battery may supply a second voltage VBAT on a level lower than that of the second voltage VBAT in a normal state. However, a case in which the level of the second voltage VBAT decreases is not limited to the case in which the battery is discharged, and may also be other cases such as when the battery is aged. When the level of the second voltage VBAT decreases, the first voltage generated based on the second voltage VBAT may also decrease.

Referring to FIG. 10, the battery charging device may be controlled to a state in which the full power transmission is permitted in a state in which the power transmission path is completely blocked. The first voltage and the gate voltage VGATE output from the charge pump may increase in the same trend. Regardless of the state of the battery charging device, the second voltage VBAT may be maintained at VB2. The first voltage may increase by a second target voltage VP2, and the gate voltage VGATE may also increase by the second target voltage VP2 in the same trend as the first voltage. The first voltage may be a value obtained by adding the selected power voltage to the second voltage VBAT.

In a state in which the gate voltage VGATE increases, the gate voltage VGATE may reach a second trigger voltage VT2. The second trigger voltage VT2 is a voltage of a lower level than that of the second target voltage VP2, and the second trigger voltage VT2 may be determined according to the second voltage VBAT. At a second point in time S2 at which the gate voltage VGATE reaches the second trigger voltage VT2, the body selector may generate a first detection signal of logic high.

At the second point in time S2, the body selector may generate the first detection signal and a third detection signal obtained by inverting the first detection signal. In response to the third detection signal, the body terminal of the switching transistor may be separated from the ground node, and in response to the first detection signal, the body terminal may be connected to the second voltage node supplying the second voltage VBAT through the resistor element. Since the second voltage VBAT is supplied to the body terminal through the resistance element, the body voltage VBODY may slowly increase from the ground voltage to the second voltage VBAT.

In an example embodiment of the present disclosure, since the second trigger voltage VT2 is determined according to the second voltage VBAT, the battery charging device may ensure that the body voltage VBODY increases. When the level of the second voltage VBAT decreases, a level of the second trigger voltage VT2, which is the gate voltage VGATE that starts outputting the first detection signal, may also decrease. Since the second trigger voltage VT2 is determined according to the second voltage VBAT, it may be ensured that the body voltage VBODY increases from the ground voltage to the second voltage VBAT even if the second voltage VBAT decreases. By ensuring that the body voltage VBODY increases from the ground voltage to the second voltage VBAT, the switching transistor may be prevented from being damaged due to the difference between the gate voltage VGATE and the body voltage VBODY.

The body selector according to an example embodiment of the present disclosure may relatively compare the first voltage and the second voltage VBAT different from the first voltage and may then sense the compared results. While the first voltage increases, when the first voltage reaches a trigger voltage that is higher than that of the second voltage VBAT, the body selector may generate a first detection signal. In response to the first detection signal, the body selector may supply the second voltage VBAT to the body terminal. The trigger voltage may be determined according to the second voltage VBAT, and when the second voltage VBAT decreases, the trigger voltage may also decrease.

In the comparative example, the body selector may compare relative ratios of a reference voltage having a fixed value and the first voltage and may then sense the compared results. When the first voltage is greater than the reference voltage, the body selector may generate a first detection signal of logic high. In an example embodiment, when the second voltage VBAT decreases, the first voltage generated from the second voltage VBAT may also decrease. When the decreased first voltage is on a level lower than that of the reference voltage, the body selector may not generate the first detection signal of logic high. Accordingly, even though the first voltage is supplied to the gate, the body terminal may not be separated from the ground node.

The body selector according to an example embodiment of the present disclosure may relatively compare the first voltage and the second voltage VBAT, not the reference voltage, and may then sense the compared results, so that the first detection signal may be generated even if both the first voltage and the second voltage VBAT decrease. When the second voltage VBAT decreases, the trigger voltage that starts generating the first detection signal also decreases, so that the body selector may ensure that the body voltage VBODY increases from the ground voltage to the second voltage VBAT. Accordingly, a difference between the gate voltage VGATE and the body voltage VBODY of the switching transistor may be stably maintained, and the performance of the battery charging device may be improved.

FIGS. 11 to 15 are views illustrating an operation of the battery charging device according to an example embodiment of the present disclosure.

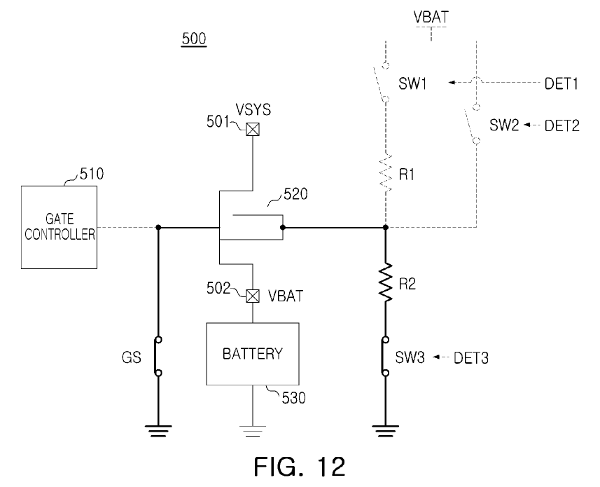

First, referring to FIGS. 11 and 12 together, before a first point in time T1, a battery charging device 500 may operate in a state in which a power transmission path is completely blocked. A gate turn-off switch GS may be connected to a ground node supplying a ground voltage, and a gate voltage VGATE may be a ground voltage. A first detection signal DET1 controlling a first switch SW1 may be a logic low and a signal obtained by inverting the first detection signal DET1, and a third detection signal DET3, obtained by inverting the first detection signal DET1, controlling the third switch SW3 may be a logic high. In response to the third detection signal DET3, the third switch SW3 may be turned on and the body terminal may be connected to the ground node. Accordingly, the body voltage VBODY may be a ground voltage, and the gate voltage VGATE and the body voltage VBODY may be substantially the same voltage. For example, a gate-body voltage VGB, which is a difference between the gate voltage VGATE and the body voltage VBODY, may be 0.

In a state in which the battery charging device 500 completely blocks the power transmission path, the second voltage VBAT of a battery voltage node 502 may be maintained at a constant voltage. For example, the battery may be isolated from the external power source. Before the first point in time T1, the charge pump may not output the first voltage QBATCP, and may not supply the first voltage QBATCP to a gate controller 510. Before the first point in time T1, both the first voltage QBATCP and the gate voltage VGATE may be ground voltages.

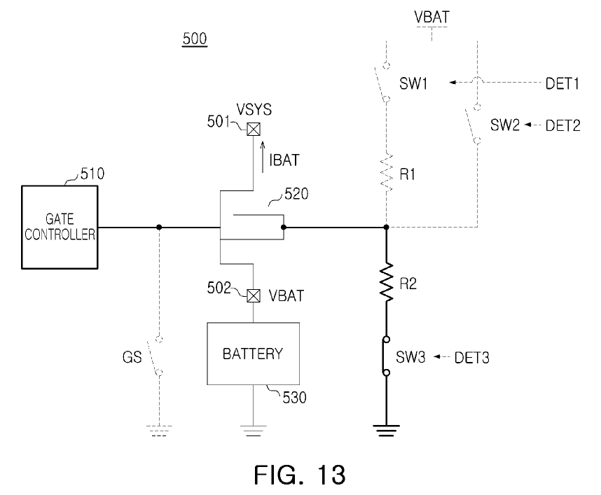

Referring to FIGS. 11 and 13 together, the battery charging device 500 may be switched to a state of permitting full power transmission after the first point in time T1. After the first point in time T1, the gate turn-off switch GS may be turned off, and a gate of the switching transistor 520 may be isolated from the ground node. The gate controller 510 may receive the first voltage QBATCP and may supply the first voltage QBATCP to the gate of the switching transistor 520 according to the gate control signal. Accordingly, as illustrated in FIG. 11, after the first point in time T1, the gate voltage VGATE may increase in substantially the same trend as the first voltage QBATCP.

After the first point in time T1, the battery charger 500 may operate in a state of permitting the full power transmission, and voltage may be supplied from the battery voltage node 502 supplying the second voltage VBAT to a system voltage node 501 supplying the system voltage VSYS, and a battery current IBAT may flow in a direction in which the second voltage VBAT is discharged.

Meanwhile, as illustrated in FIG. 11, even after the first point in time T1, the first detection signal DET1 may maintain a logic low state. Accordingly, in response to the third detection signal DET3 in which the first detection signal DET1 is inverted, the third switch SW3 may maintain a turned-on state, and the body terminal may be connected to the ground node. After the first point in time T1, the body voltage VBODY may be the ground voltage and the gate voltage VGATE increases in the same trend as the first voltage QBATCP, so that the gate-body voltage VGB, which is a difference between the gate voltage VGATE and the body voltage VBODY, may increase.

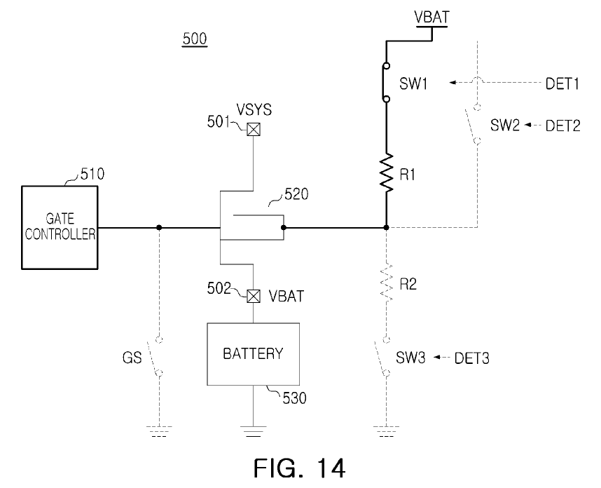

Referring to FIGS. 11 and 14 together, the system voltage VSYS may reach the second voltage VBAT at a second point in time T2 after the first point in time T1. The gate voltage VGATE may increase in the same trend as the first voltage QBATCP output from the charge pump. The body selector may sense the relative ratios of the first voltage QBATCP and the second voltage VBAT output from the charge pump, and may generate a first detection signal DET1 of logic high when the first voltage QBATCP increases by a level higher than that of the second voltage VBAT.

For example, the first voltage QBATCP may be a voltage output from the charge pump, and the second voltage VBAT may be a battery voltage. The first voltage QBATCP may be a voltage obtained by adding the second voltage VBAT to a selected power voltage. In an example embodiment, the selected power voltage may be a maximum power voltage selected from the power voltages within the chip implementing the mobile device.

At the second point in time T2, the first switch SW1 may be turned on in response to the first detection signal DET1. The body terminal may be connected to the battery voltage node 502 supplying the second voltage VBAT through the first resistor R1, and the body voltage VBODY may be slowly increased from the ground voltage to the second voltage VBAT by the first resistor R1. The third switch SW3 may be turned off in response to the third detection signal DET3 obtained by inverting the first detection signal DET1, and the body terminal may be separated from the ground node.

The battery charging device 500 according to an example embodiment of the present disclosure may turn on the first switch SW1 at the second point in time T2 so that the switching transistor 520 is not damaged, as the gate-body voltage VGB, which is a difference between the gate voltage VGATE and the body voltage VBODY, increases. Since the second voltage VBAT is supplied to the body terminal through the first switch SW1 turned on at the second point in time T2, as illustrated in FIG. 11, the body voltage VBODY may increase from the second point in time T2. Accordingly, due to an increase in the gate voltage VGATE, the gate-body voltage VGB may be prevented from exceeding the maximum voltage that the switching transistor 520 may withstand, and damage to the switching transistor 520 may be prevented.

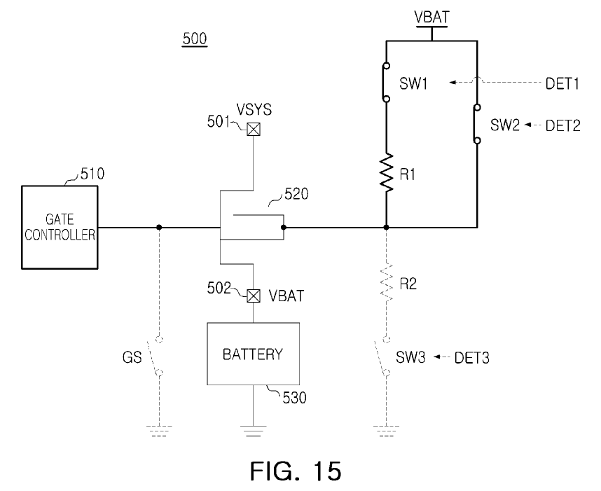

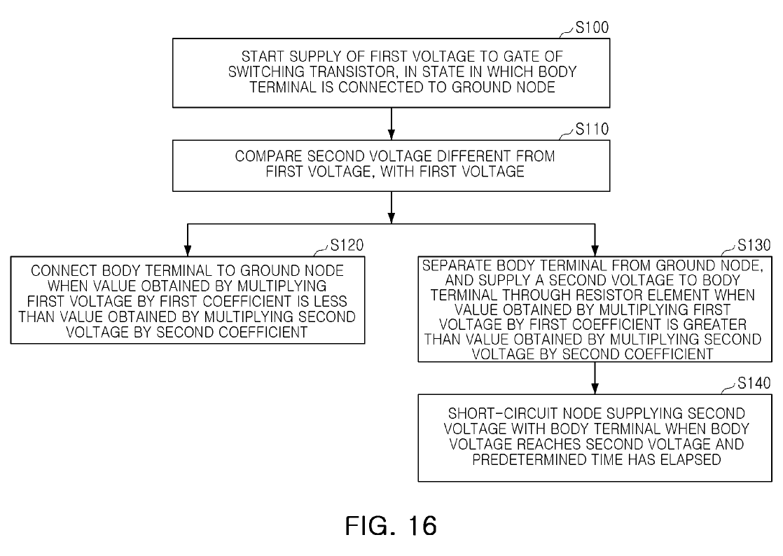

Referring to FIGS. 11 and 15 together, the body voltage VBODY may reach the second voltage VBAT at a third point in time T3 after the second point in time T2. At the third point in time T3, the body selector may generate the second detection signal DET2 delaying the first detection signal DET1 for a predetermined time. For example, the predetermined time may be determined according to the capacity of a battery 530 and the first resistor R1.

In an example embodiment, the time taken for the gate voltage VGATE to be separated from the ground node and reach the first voltage QBATCP may be longer than a predetermined time taken for the first detection signal DET1 to be input to a debounce delay circuit and output the second detection signal DET2. Referring to FIG. 11, the predetermined time may be the time from the second point in time T2 to the third point in time T3.

In response to the second detection signal DET2, the second switch SW2 may be turned on, and the battery voltage node 502 supplying the second voltage VBAT may be short-circuited with the body terminal. For example, as the second switch SW2 is turned on, the battery voltage node 502 may be short-circuited with the body terminal. As the battery voltage node 502 and the body terminal are short-circuited, the second voltage VBAT may be stably supplied to the body terminal.

Referring to FIG. 11, at a fourth point in time T4 after the third point in time T3, the battery charging device 500 may be switched from a state of permitting full power transmission to a state of completely blocking the power transmission path. When the gate turn-off switch GS is connected to the ground node, the battery charging device 500 may operate in a state completely blocking the power transmission path.

At the fourth point in time T4, the charge pump stops outputting the first voltage QBATCP, and thus, the first voltage QBATCP may not be supplied to the gate. The body selector may generate a third detection signal DET3 of logic high, and in response to the third detection signal DET3, the third switch SW3 may be turned on, and the body terminal may be connected to the ground node. Since the body terminal and the gate are each connected to the ground node, the gate voltage VGATE and the body voltage VBODY may be substantially the same voltage. For example, the gate-body voltage VGB, which is the difference between the gate voltage VGATE and the body voltage VBODY, may be 0.

FIG. 16 is a flowchart illustrating an operating method of a battery charging device according to an example embodiment of the present disclosure.

The battery charging device according to an example embodiment of the present disclosure may include a gate driving circuit, a switching transistor, and a body selector. The switching transistor may have a triple well structure in which a first well region and a second well region disposed within the first well region and providing the body terminal are electrically connected to each other. The gate driving circuit may adjust a voltage supplied to the gate of the switching transistor, and the body selector may adjust a voltage supplied to the body terminal of the switching transistor.

When the battery charging device is in a state in which the power transmission path is completely blocked, a gate of the switching transistor may be connected to a ground node, and the body terminal of the switching transistor may also be connected to a ground node. For example, when the battery charging device is in a state in which the power transmission path is completely blocked, the battery may be in a discharged state or may not be charged by an external power source.

To switch the battery charger from a state in which the power transmission path is completely blocked to a state in which the full power transmission is permitted, a gate turn-off switch connected between the gate and the ground node of the switching transistor may be turned off. The gate turn-off switch may be turned off, so that the gate of the switching transistor may be separated from the ground node. The gate controller may receive a gate control signal for switching a state of the battery charger to a state of permitting the full power transmission.

In a state in which the body terminal is connected to the ground node, a first voltage may be supplied to the gate of the switching transistor (S100). The gate controller may receive a first voltage from a charge pump and may supply the first voltage to the gate by the gate control signal. The first voltage and the gate voltage output from the charge pump may increase in the same trend. The first voltage may be a value, which is the sum of a second voltage different from the first voltage, and a selected power voltage. In an example embodiment, the selected power voltage may be a maximum power voltage selected from power voltages within the chip implementing the mobile device.

The body selector may compare the second voltage, different from the first voltage, with the first voltage (S110). The body selector according to an example embodiment of the present disclosure may sense the relative ratios of the first voltage and the second voltage, and may control the voltage supplied to the body terminal. The relative ratios of the first voltage and the second voltage may be compared to ensure that the body voltage is switched. By ensuring that the body voltage increases from the ground voltage to the second voltage, the gate-body voltage may be prevented from exceeding the maximum voltage that the switching transistor may withstand due to the increase in the gate voltage, and damage to the switching transistor may be prevented.

When a value obtained by multiplying the first voltage by the first coefficient is less than a value obtained by multiplying the second voltage by the second coefficient, the body terminal may be connected to the ground node (S120). When a value obtained by multiplying the first voltage supplied to the gate by the first coefficient is less than the value obtained by multiplying the second voltage by the second coefficient, even if the ground voltage is supplied to the body terminal, the gate-body voltage may be on a level lower than that of the maximum voltage that the switching transistor may withstand. Accordingly, the switching transistor may not be damaged.

When the value obtained by multiplying the first voltage by the first coefficient is greater than the value obtained by multiplying the second voltage by the second coefficient, the body terminal may be separated from the ground node, and a second voltage may be supplied to the body terminal through the resistor element (S130). When the body voltage increases rapidly, a battery peak current flowing in a direction in which the battery is discharged may occur, and damage may occur to the battery charging circuit due to the battery peak current. To prevent the body voltage from increasing rapidly, the body selector may supply the second voltage to the body terminal through the resistor element. When the second voltage is supplied to the body terminal through the resistor element, the body voltage may slowly increase from the ground voltage to the second voltage. As the body voltage slowly increases, the battery charging device may prevent the gate-body voltage from exceeding the maximum voltage that the switching transistor may withstand, and damage to the switching transistor may be prevented.

When the body voltage reaches the second voltage and a predetermined time has elapsed, a node supplying the second voltage may be short-circuited with the body terminal (S140). The body selector may stably supply the second voltage to the body terminal by directly connecting the body terminal to the node supplying the second voltage.

According to an example embodiment of the present disclosure, the switching transistor may have a triple well structure in which the first well region and the second well region disposed within the first well region and providing the body terminal are electrically connected to each other, so that a parasitic path formed in the switching transistor may be blocked, and a power transmission path of the battery charging device may be smoothly provided. The body selector included in a battery charger may sense the relative ratios of the first voltage and the second voltage to control the voltage supplied to the body terminal, thereby preventing the gate-body voltage from exceeding the maximum voltage that the switching transistor may withstand, and preventing damage to the switching transistor.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A battery charging device, comprising:
a switching transistor including a first well region doped with a first impurity, a second well region disposed within the first well region and doped with a second impurity, different from the first impurity, a source region and a drain region disposed within the second well region and doped with the first impurity, a body terminal disposed within the second well region and doped with the second impurity and electrically connected to the first well region, and a gate disposed between the source region and the drain region;
a gate driving circuit including a gate controller receiving a first voltage and adjusting a gate voltage input to the gate, and a gate turn-off switch connected between a ground node supplying a ground voltage and the gate; and
a body selector generating a first detection signal using the first voltage and a second voltage different from the first voltage, and adjusting a voltage supplied to the body terminal,
wherein the body selector connects the body terminal to a node supplying the second voltage in response to the first detection signal and a second detection signal delaying the first detection signal during a predetermined time, and connecting the body terminal to the ground node in response to a third detection signal obtained by inverting the first detection signal.

2. The battery charging device of claim 1, wherein the body selector includes:
a first switch connected between the body terminal and the node supplying the second voltage, and turned on in response to the first detection signal;
a second switch connected in parallel with the first switch between the body terminal and the node supplying the second voltage, and turned on in response to the second detection signal;
a third switch connected between the body terminal and the ground node, and turned on in response to the third detection signal;
a first resistor connected between the body terminal and the first switch; and
a second resistor connected between the body terminal and the third switch.

3. The battery charging device of claim 2, wherein the predetermined time is determined according to a resistance of the first resistor.

4. The battery charging device of claim 1, wherein the body selector includes:
a first sensing resistor and a second sensing resistor connected in series between a node supplying the first voltage and the ground node;
a third sensing resistor and a fourth sensing resistor connected in series between the node supplying the second voltage and the ground node; and
a comparator comparing a first sensing voltage applied to the second sensing resistor and a second sensing voltage applied to the fourth sensing resistor and outputting the first detection signal.

5. The battery charging device of claim 1, wherein the body selector includes:
a first sensing resistor and a second sensing resistor connected in series between a node supplying the first voltage and the ground node;
a third sensing resistor, a fourth sensing resistor and a fifth sensing resistor connected in series between the node supplying the second voltage and the ground node;
a multiplexer selecting and outputting one of a first sensing voltage applied to the fourth sensing resistor and the fifth sensing resistor, and a second sensing voltage applied to the fifth sensing resistor; and
a comparator comparing a third sensing voltage applied to the second sensing resistor and a voltage output from the multiplexer, and outputting the first detection signal.

6. The battery charging device of claim 5, wherein the body selector further includes a latch connected to an output terminal of the comparator and storing the first detection signal.

7. The battery charging device of claim 1, wherein the body selector further includes:
a debounce delay circuit delaying the first detection signal during the predetermined time and outputting the second detection signal; and
an inverter obtained by inverting the first detection signal and outputting the third detection signal.

8. The battery charging device of claim 1, wherein the first voltage is a sum of the second voltage and a selected power voltage.

9. The battery charging device of claim 1, wherein when the gate turn-off switch is turned on and the gate is connected to the ground node, the body selector supplies the ground voltage to the body terminal.

10. The battery charging device of claim 1, wherein when the gate turn-off switch is turned off and the gate is separated from the ground node, the body selector supplies the second voltage to the body terminal.

11. The battery charging device of claim 1, wherein the gate controller receives a gate control signal and determines a voltage supplied to the gate in response to the gate control signal.

12. The battery charging device of claim 1, wherein the second voltage is supplied to the source region, and the drain region is connected to a node supplying a system voltage.

13. An operating method of a battery charging device including a switching transistor having a triple well structure in which a first well region and a second well region disposed within the first well region and providing a body terminal are electrically connected to each other, the method comprising:
starting a supply of a first voltage to a gate of the switching transistor in a state in which the body terminal is connected to a ground node;
comparing a second voltage different from the first voltage with the first voltage;
when a value obtained by multiplying the first voltage by a first coefficient is greater than a value obtained by multiplying the second voltage by a second coefficient different from the first coefficient, separating the body terminal from the ground node, and supplying the second voltage to the body terminal through a resistance element; and
short-circuiting a node supplying the second voltage with the body terminal when a body voltage reaches the second voltage and a predetermined time has elapsed.

14. The operating method of the battery charging device of claim 13, wherein the first coefficient and the second coefficient are each greater than 0 and less than or equal to 1.

15. The operating method of the battery charging device of claim 13, further comprising:
when the gate is connected to the ground node, connecting the body terminal to the ground node.

16. The operating method of the battery charging device of claim 13, wherein in the supplying the second voltage to the body terminal through the resistance element, a gate voltage is a trigger voltage lower than the first voltage, and the trigger voltage is determined according to the second voltage.

17. The operating method of the battery charging device of claim 13, wherein a first time required for a gate voltage to be separated from the ground node and reach the first voltage is longer than the predetermined time.

18. The operating method of the battery charging device of claim 13, further comprising:
when a value obtained by multiplying the first voltage by the first coefficient is less than a value obtained by multiplying the second voltage by the second coefficient,
connecting the body terminal to the ground node.

19. A mobile device, comprising:
a system including a processor, a memory and a storage;
a battery providing a power source for driving the system and charged by a system voltage generated by an external power source; and
a battery charging device including a switching transistor controlling a supply of the system voltage to the battery and a body selector controlling a voltage supplied to a body terminal of the switching transistor,
wherein the switching transistor has a triple well structure in which a first well region and a second well region disposed within the first well region and providing the body terminal are electrically connected to each other,
at a first point in time, a supply of a first voltage to a gate of the switching transistor is started, and the battery charging device supplies a power source from the battery to the system,
at a second point in time after the first point in time, the body selector separates the body terminal from a ground node and supplies a second voltage output from the battery to the body terminal through a resistance element, and
at a third point in time after the second point in time, when a body voltage reaches the second voltage and a predetermined time has elapsed, the body selector short-circuits a node supplying the second voltage with the body terminal.

20. The mobile device of claim 19, wherein the battery is separated from the external power source.
